(19) United States
(12) Patent Application Publication
(10) Pub. No.: US 2023/0320143 A1
(43) Pub. Date: Oct. 5, 2023

(54) ORGANIC LIGHT-EMITTING DISPLAY APPARATUS AND METHOD OF MANUFACTURING THE SAME

(71) Applicant: Samsung Display Co., Ltd., Yongin-si (KR)

(72) Inventors: Dongha Lee, Yongin-si (KR); Seulgi Han, Yongin-si, (KR)

(73) Assignee: Samsung Display Co., Ltd., Yongin-si (KR)

(21) Appl. No.: 18/295,465

(22) Filed: Apr. 4, 2023

(30) Foreign Application Priority Data
Apr. 5, 2022 (KR) 10-2022-0042522

(51) Int. Cl. H10K 59/124; H10K 71/00; H10K 59/121

(52) U.S. Cl. CPC H10K 59/124; H10K 71/00; H10K 59/1213; H10K 2102/351

(57) ABSTRACT

An organic light-emitting display apparatus includes a pixel electrode above a substrate, an insulating layer covering an edge of the pixel electrode and including an opening exposing a central portion of the pixel electrode, a first functional layer disposed on the pixel electrode exposed by the opening and including a convex upper surface, a second functional layer disposed on the first functional layer and including a planarized upper surface, an organic emission layer disposed on the second functional layer, and an opposite electrode disposed on the organic emission layer.

### CROSS-REFERENCE TO RELATED APPLICATION(S)

This application claims priority to and benefits of Korean Patent Application No. 10-2022-0042522 under 35 U.S.C. § 119, filed on Apr. 5, 2022 in the Korean Intellectual Property Office, the entire contents of which are incorporated herein by reference.

### BACKGROUND

### 1. Technical Field

One or more embodiments relate to an organic light-emitting display apparatus in which the flatness of a thin film is improved by eliminating the non-uniformity of an organic thin film layer, and a method of manufacturing such an organic light-emitting display apparatus.

### 2. Description of the Related Art

Among display apparatuses, an organic light-emitting display apparatus has been attracting attention as a next-generation display apparatus due to advantages, such as a wide viewing angle, a high contrast ratio, and a fast response time.

In general, an organic light-emitting display apparatus has a pixel-defining layer covering the edge of a pixel electrode and exposing the central portion of the pixel electrode. After the pixel-defining layer is formed, an intermediate layer including an emission layer may be formed on the pixel electrode by using a method, such as inkjet printing or nozzle printing.

### SUMMARY

However, in an organic light-emitting display apparatus and a method of manufacturing the same according to the related art, in case that an intermediate layer is formed, the thickness of the intermediate layer formed in a pixel may not be uniform, and thus, the long-term reliability of an organic light-emitting display panel degrades, for example, stains occur and current density for each location differs.

To solve various problems including the above problem, one or more embodiments include an organic light-emitting display apparatus in which the flatness of a thin film may be improved by eliminating the non-uniformity of an organic thin film layer and a method of manufacturing the organic light-emitting display apparatus. However, such a technical problem is an example, and one or more embodiments are not limited thereto.

Additional aspects will be set forth in part in the description which follows and, in part, will be apparent from the description, or may be learned by practice of the embodiments of the disclosure.

According to one or more embodiments, an organic light-emitting display apparatus may include a pixel electrode above a substrate, an insulating layer covering an edge of the pixel electrode and including an opening exposing a central portion of the pixel electrode, a first functional layer disposed on the pixel electrode exposed by the opening and including a convex upper surface, a second functional layer disposed on the first functional layer and including a planarized upper surface, an organic emission layer disposed on the second functional layer, and an opposite electrode disposed on the organic emission layer.

The first functional layer may include a hole injection function.

The second functional layer may include a hole injection function.

The first functional layer and the second functional layer may include a curable material.

A bottom surface of the second functional layer may be concave.

A thickness of the second functional layer may be least at the center thereof and may gradually increase toward the insulating layer.

Molecular weights of the first functional layer and the second functional layer may be different from each other.

A molecular weight of the first functional layer may be greater than a molecular weight of the second functional layer.

The first functional layer and the second functional layer may include the same material as each other or different materials from each other.

According to one or more embodiments, a method of manufacturing an organic light-emitting display apparatus may include forming a pixel electrode above a substrate, forming an insulating layer covering an edge of the pixel electrode and including an opening exposing a central portion of the pixel electrode, forming a first functional layer on the pixel electrode exposed by the opening, the first functional layer including a convex upper surface, forming a second functional layer on the first functional layer, the second functional layer having a planarized upper surface, forming an organic emission layer on the second functional layer, and forming an opposite electrode on the organic emission layer.

The forming of the first functional layer may include setting a temperature in a chamber to a first temperature, reducing pressure in the chamber to a first pressure, and drying the first functional layer under conditions of the first temperature and the first pressure.

The forming of the second functional layer may include setting the temperature in the chamber to a second temperature that may be lower than the first temperature, controlling the pressure in the chamber to a second pressure that may be higher than the first pressure, and drying the second functional layer under conditions of the second temperature and the second pressure.

The first temperature may be about 50° C. or greater, and the second temperature may be less than about 50° C.

The second pressure may be maintained at about 0.01 Torr or greater.

The first pressure may be about 1×10⁻⁵ Torr.

The reducing of the pressure in the chamber to the first pressure may include reducing the pressure in the chamber to the first pressure by using a turbo pump.

The first functional layer and the second functional layer may include a hole injection function.

The first functional layer and the second functional layer may include a curable material.

A bottom surface of the second functional layer may be concave.

A thickness of the second functional layer may be least at the center thereof and may gradually increase toward the insulating layer

These general and specific embodiments may be implemented by using a system, a method, a computer program, or a combination thereof.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a portion of a display apparatus according to an embodiment;

FIGS. 2 to 4 are schematic circuit diagrams of a pixel that may be included in a display apparatus according to an embodiment;

FIG. 5 is a schematic cross-sectional view of a structure of an organic light-emitting diode that may be employed in a display apparatus according to an embodiment;

FIG. 6 is a schematic cross-sectional view of a portion of an organic light-emitting display apparatus according to an embodiment;

FIGS. 7 and 8 are enlarged schematic cross-sectional views of an intermediate layer of an organic light-emitting diode according to an embodiment;

FIGS. 9 to 12 are schematic cross-sectional views of a method of manufacturing an organic light-emitting display apparatus, according to an embodiment;

FIG. 13 is a schematic graph showing changes in chamber pressure in case that ‘quick drying’ and ‘slow drying’ according to the disclosure are used respectively; and

FIG. 14 is a schematic graph showing profiles of functional layers formed in case that ‘quick drying’ and ‘slow drying’ according to the disclosure are applied respectively thereto.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As used herein, the term “and/or” includes any and all combinations of one or more of the associated listed items. For example, “A and/or B” may be understood to mean any combination including “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. For example, intervening layers, regions, or elements may be present.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

It will be understood that the terms “connected to” or “coupled to” may include a physical or electrical connection or coupling.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a certain process order may be performed differently from the described order. For example, two consecutively described processes may be performed substantially at the same time or performed in an order opposite to the described order.

Sizes of elements in the drawings may be exaggerated or reduced for convenience of explanation. For example, since sizes and thicknesses of elements in the drawings may be arbitrarily illustrated for convenience of explanation, the following embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

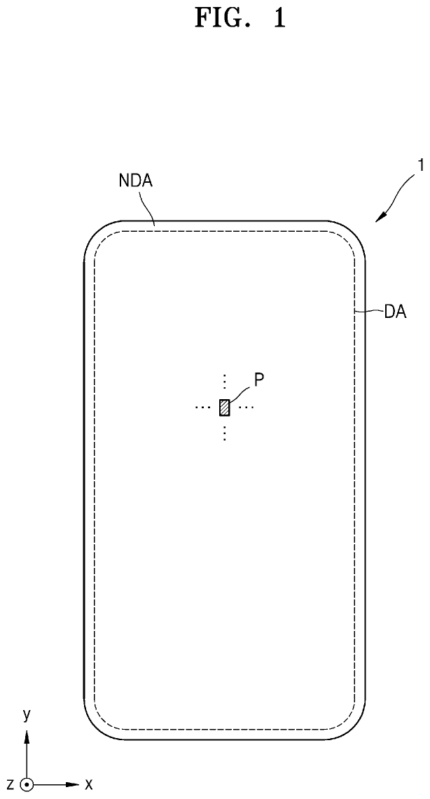

FIG. 1 is a schematic plan view of a portion of a display apparatus 1 according to an embodiment.

Referring to FIG. 1, the display apparatus 1 includes a display area DA and a peripheral area NDA outside the display area DA. Pixels P including display elements may be arranged in the display area DA, and the display apparatus 1 may provide an image by using light emitted from the pixels P arranged in the display area DA. The peripheral area NDA may be a non-display area in which display elements are not arranged, and the display area DA may be entirely surrounded by the peripheral area NDA.

Although FIG. 1 shows the display apparatus 1 including a flat display surface, one or more embodiments are not limited thereto. In another embodiment, the display apparatus 1 may include a stereoscopic display surface or a curved display surface.

In case that the display apparatus 1 includes a stereoscopic display surface, the display apparatus 1 may include multiple display areas indicating different directions, and for example, may include a polygonal columnar display surface. In another embodiment, in case that the display apparatus 1 includes a curved display surface, the display apparatus 1 may be implemented in various forms, such as a flexible, foldable, or rollable display apparatus.

In an embodiment, FIG. 1 shows the display apparatus 1 applicable to a mobile phone terminal. Although not shown, electronic modules, a camera module, a power module, and the like mounted on a mainboard may be arranged together with the display apparatus 1 in a bracket/case, etc., thereby constituting a mobile phone terminal. The display apparatus 1 described herein may be applied to large-sized electronic devices, such as a television and a monitor, and may also be applied to small and medium-sized electronic devices, such as a tablet personal computer, a vehicle navigation system, a game console, and a smartwatch.

Although FIG. 1 shows a case in which the display area DA of the display apparatus 1 has a rectangular shape with round corners, in another embodiment, the shape of the display area DA may be a circle, an oval, or a polygon, such as a triangle or a pentagon.

The display area DA of the display apparatus 1 may include a component area in which the arrangement of the pixels P may be different from that of the periphery. The display apparatus 1 may include a display panel, and for example, a sensor, a camera, etc. may be arranged on a side of the display panel to overlap the component area. In another embodiment, the component area may be in the peripheral area NDA.

Although an organic light-emitting display apparatus is described below as an example of the display apparatus 1 according to an embodiment, a display apparatus described herein is not limited thereto. In another embodiment, the display apparatus 1 described herein may be a display apparatus, such as an inorganic light-emitting display apparatus (or an inorganic electroluminescent (EL) display apparatus) or a quantum dot light-emitting display apparatus. For example, an emission layer of a display element provided in the display apparatus 1 may include an organic material, an inorganic material, quantum dots, an organic material and quantum dots, or an inorganic material and quantum dots.

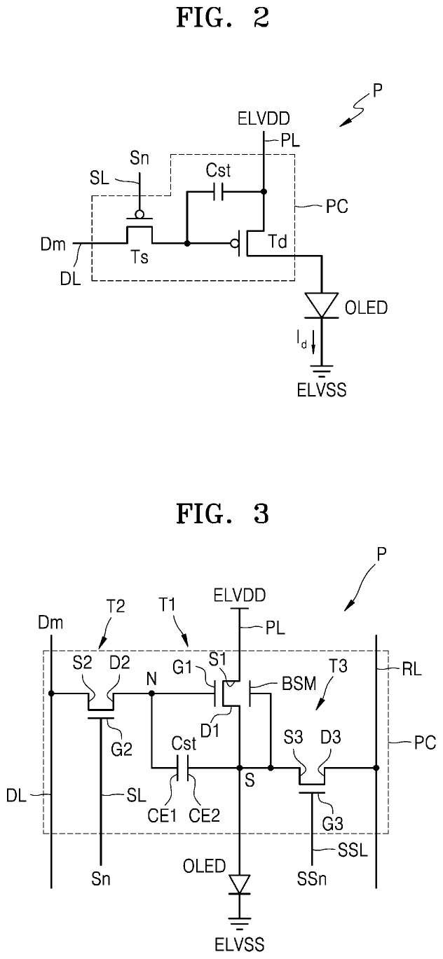

FIGS. 2 to 4 are schematic circuit diagrams of a pixel P that may be included in the display apparatus 1 according to an embodiment.

Referring to FIG. 2, each pixel P may include a pixel circuit PC connected to a scan line SL and a data line DL and an organic light-emitting diode OLED connected to the pixel circuit PC.

The pixel circuit PC may include a driving thin-film transistor Td, a switching thin-film transistor Ts, and a storage capacitor Cst. The switching thin-film transistor Ts may be connected to the scan line SL and the data line DL and may be configured to transmit a data signal Dm input through the data line DL to the driving thin-film transistor Td according to a scan signal Sn input through the scan line SL.

The storage capacitor Cst may be connected to the switching thin-film transistor Ts and a driving voltage line PL and may store a voltage corresponding to a difference between a voltage received from the switching thin-film transistor Ts and a driving voltage ELVDD supplied to the driving voltage line PL.

The driving thin-film transistor Td may be connected to the driving voltage line PL and the storage capacitor Cst and may be configured to control a driving current I_{d} flowing through the organic light-emitting diode OLED from the driving voltage line PL, in response to a voltage value stored in the storage capacitor Cst. The organic light-emitting diode OLED may emit light having certain luminance according to the driving current I_{d}.

Although FIG. 2 shows a case in which the pixel circuit PC includes two thin-film transistors and a storage capacitor, one or more embodiments are not limited thereto. In another embodiment, the pixel circuit PC may include seven thin-film transistors and a storage capacitor. In another embodiment, the pixel circuit PC may include two or more storage capacitors.

Referring to FIG. 3, the pixel circuit PC may include a driving thin-film transistor T1, a switching thin-film transistor T2, a sensing thin-film transistor T3, and the storage capacitor Cst.

The scan line SL may be connected to a gate electrode G2 of the switching thin-film transistor T2, the data line DL may be connected to a source electrode S2 of the switching thin-film transistor T2, and a first electrode CE1 of the storage capacitor Cst may be connected to a drain electrode D2 of the switching thin-film transistor T2.

Accordingly, the switching thin-film transistor T2 may be configured to supply a data voltage of the data line DL to a first node N, in response to the scan signal Sn from the scan line SL of each pixel P.

A gate electrode G1 of the driving thin-film transistor T1 may be connected to the first node N, a source electrode S1 of the driving thin-film transistor T1 may be connected to the driving voltage line PL configured to transfer the driving voltage ELVDD, and a drain electrode D1 of the driving thin-film transistor T1 may be connected to an anode electrode of the organic light-emitting diode OLED.

Accordingly, the driving thin-film transistor T1 may be configured to adjust an amount of current flowing through the organic light-emitting diode OLED, based on a gate-source voltage of the driving thin-film transistor T1 itself, for example, a voltage applied between the driving voltage ELVDD and the first node N.

A sensing control line SSL may be connected to a gate electrode G3 of the sensing thin-film transistor T3, a source electrode S3 of the sensing thin-film transistor T3 may be connected to a second node S, and a drain electrode D3 of the sensing thin-film transistor T3 may be connected to a reference voltage line RL. In an embodiment, the sensing thin-film transistor T3 may be controlled by the scan line SL instead of the sensing control line SSL.

The sensing thin-film transistor T3 may sense an electric potential of a first electrode (e.g., the anode) of the organic light-emitting diode OLED. The sensing thin-film transistor T3 may be configured to supply a pre-charging voltage from the reference voltage line RL to the second node S, in response to a sensing signal SSn from the sensing control line SSL, or supply a voltage of a first electrode (e.g., the anode) of the organic light-emitting diode OLED to the reference voltage line RL during a sensing period.

The storage capacitor Cst may have the first electrode CE1 connected to the first node N and a second electrode CE2 connected to the second node S. The storage capacitor Cst may be charged with a difference voltage between voltages supplied to the first and second nodes N and S, respectively, and thus may supply the charged voltage as a driving voltage of the driving thin-film transistor T1. For example, the storage capacitor Cst may be charged with a difference voltage between a data voltage Dm and a pre-charging voltage supplied to the first and second nodes N and S, respectively.

A bias electrode BSM may correspond to the driving thin-film transistor T1 and be connected to the source electrode S3 of the sensing thin-film transistor T3. Because the bias electrode BSM may receive a voltage while being interlocked with an electric potential of the source electrode S3 of the sensing thin-film transistor T3, the driving thin-film transistor T1 may be stabilized. In an embodiment, the bias electrode BSM may not be connected to the source electrode S3 of the sensing thin-film transistor T3 and may be connected to a separate bias wiring.

A second electrode (e.g., a cathode) of the organic light-emitting diode OLED may receive a common voltage ELVSS. The organic light-emitting diode OLED may receive a driving current from the driving thin-film transistor T1 and emit light.

Although FIG. 3 shows a case in which signal lines, e.g., the scan line SL, the sensing control line SSL, and the data line DL, the reference voltage line RL, and the driving voltage line PL are provided for each pixel P, one or more embodiments are not limited thereto. For example, at least one of the signal lines, e.g., the scan line SL, the sensing control line SSL, and the data line DL, and/or the reference voltage line RL, and the driving voltage line PL may be shared by neighboring pixels.

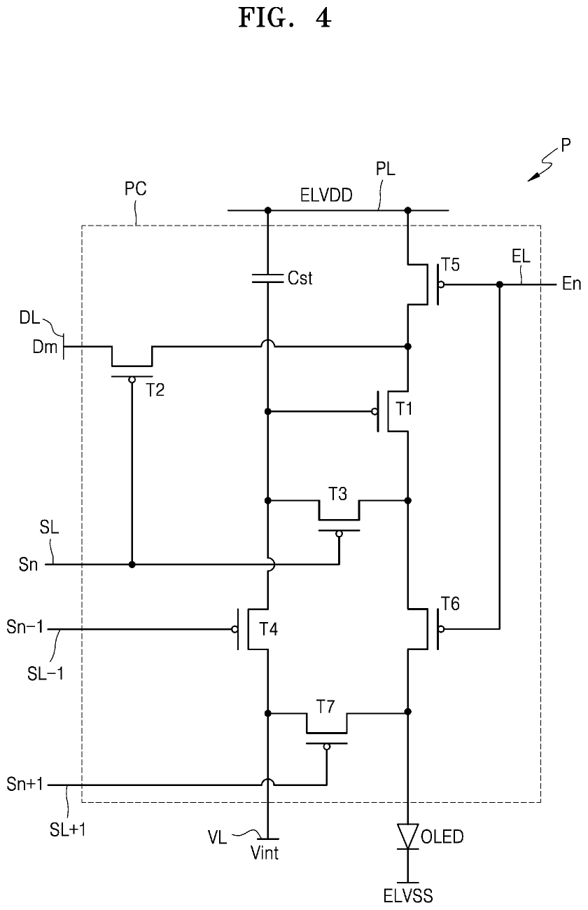

Referring to FIG. 4, a pixel circuit PC may include a driving thin-film transistor T1, a switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 4 shows a case in which signal lines, e.g., a scan line SL, a previous scan line SL−1, a next scan line SL+1, an emission control line EL, and a data line DL, an initialization voltage line VL, and a driving voltage line PL are provided for each pixel circuit PC, one or more embodiments are not limited thereto. In another embodiment, at least one of the signal lines, e.g., a scan line SL, a previous scan line SL−1, a next scan line SL+1, an emission control line EL, and a data line DL, and/or the initialization voltage line VL may be shared by neighboring pixel circuits.

A drain electrode of the driving thin-film transistor T1 may be electrically connected to the organic light-emitting diode OLED via the emission control thin-film transistor T6. The driving thin-film transistor T1 may receive the data signal Dm according to a switching operation of the switching thin-film transistor T2 and thus may supply a driving current to the organic light-emitting diode OLED.

A gate electrode of the switching thin-film transistor T2 may be connected to the scan line SL, and a source electrode of the switching thin-film transistor T2 may be connected to the data line DL. A drain electrode of the switching thin-film transistor T2 may be connected to a source electrode of the driving thin-film transistor T1 and may also be connected to the driving voltage line PL via the operation control thin-film transistor T5.

The switching thin-film transistor T2 may be turned on according to the scan signal Sn received through the scan line SL and thus may perform a switching operation for transmitting the data signal Dm transferred through the data line DL to the source electrode of the driving thin-film transistor T1.

A gate electrode of the compensation thin-film transistor T3 may be connected to the scan line SL. A source electrode of the compensation thin-film transistor T3 may be connected to the drain electrode of the driving thin-film transistor T1 and may also be connected to a pixel electrode of the organic light-emitting diode OLED via the emission control thin-film transistor T6. A drain electrode of the compensation thin-film transistor T3 may be connected to a first electrode of the storage capacitor Cst, a source electrode of the first initialization thin-film transistor T4, and a gate electrode of the driving thin-film transistor T1. The compensation thin-film transistor T3 may be turned on according to the scan signal Sn received through the scan line SL and thus may diode-connect the driving thin-film transistor T1 by connecting the gate electrode and the drain electrode of the driving thin-film transistor T1 to each other.

A gate electrode of the first initialization thin-film transistor T4 may be connected to the previous scan line SL−1. A drain electrode of the first initialization thin-film transistor T4 may be connected to the initialization voltage line VL. The source electrode of the first initialization thin-film transistor T4 may be connected to the first electrode of the storage capacitor Cst, the drain electrode of the compensation thin-film transistor T3, and the gate electrode of the driving thin-film transistor T1. The first initialization thin-film transistor T4 may be turned on according to a previous scan signal Sn−1 received through the previous scan line SL−1 and thus may perform an initialization operation for initializing a voltage of the gate electrode of the driving thin-film transistor T1 by transmitting an initialization voltage Vint to the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the organic light-emitting diode OLED. As the operation control thin-film transistor T5 and the emission control thin-film transistor T6 may be simultaneously turned on according to an emission control signal En received through the emission control line EL, the driving voltage ELVDD may be transmitted to the organic light-emitting diode OLED, and thus, a driving current may flow through the organic light-emitting diode OLED.

A gate electrode of the second initialization thin-film transistor T7 may be connected to the next scan line SL+1. A source electrode of the second initialization thin-film transistor T7 may be connected to the pixel electrode of the organic light-emitting diode OLED. A drain electrode of the second initialization thin-film transistor T7 may be connected to the initialization voltage line VL. The second initialization thin-film transistor T7 may be turned on according to a next scan signal Sn+1 received through the next scan line SL+1 and thus may initialize the pixel electrode of the organic light-emitting diode OLED.

Although FIG. 4 shows a case in which the first initialization thin-film transistor T4 and the second initialization thin-film transistor T7 are connected to the previous scan line SL−1 and the next scan line SL+1, respectively, one or more embodiments are not limited thereto. In another embodiment, both of the first initialization thin-film transistor T4 and the second initialization thin-film transistor T7 may be connected to the previous scan line SL−1 and driven according to the previous scan signal Sn−1.

A second electrode of the storage capacitor Cst may be connected to the driving voltage line PL. A first electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (e.g., a cathode) of the organic light-emitting diode OLED may receive the common voltage ELVSS. The organic light-emitting diode OLED may receive a driving current from the driving thin-film transistor T1 and emit light.

A pixel circuit according to an embodiment is not limited to the numbers of thin-film transistors and storage capacitors and the circuit design described with reference to FIGS. 2 to 4, and the numbers of thin-film transistors and storage capacitors and the circuit design may be variously modified.

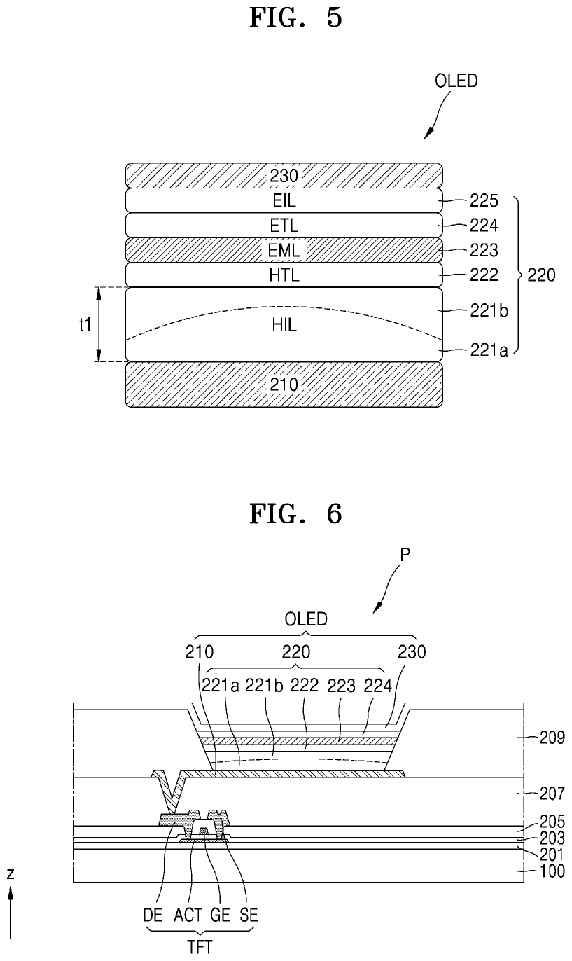

FIG. 5 is a schematic cross-sectional view of a structure of the organic light-emitting diode OLED that may be employed in a display apparatus according to an embodiment.

Referring to FIG. 5, the organic light-emitting diode OLED may be a light-emitting element and may be included in each pixel P (refer to FIG. 1). The organic light-emitting diode OLED may be electrically connected to the pixel circuit PC described with reference to FIGS. 2 to 4 and thus may receive power and a signal through the pixel circuit PC, thereby controlling the degree of light emission.

The organic light-emitting diode OLED may include a pixel electrode 210, an opposite electrode 230, and an intermediate layer 220 between the pixel electrode 210 and the opposite electrode 230. The pixel electrode 210 and the intermediate layer 220 may be patterned for each organic light-emitting diode OLED, and the opposite electrode 230 may be provided as one body in multiple organic light-emitting diodes OLED.

In an embodiment, the intermediate layer 220 may be individually provided on the pixel electrode 210 of each pixel by using an inkjet printing method. As described below, the intermediate layer 220 may include a first functional layer 221a, a second functional layer 221b, a third functional layer 222, an organic emission layer EML 223, a fourth functional layer 224, and a fifth functional layer 225. Among the layers, the remaining layers excluding the first functional layer 221a, the second functional layer 221b, and the organic emission layer 223 may be selectively included, and other functional layers may be further included.

The first functional layer 221a and the second functional layer 221b may be disposed on the pixel electrode 210. The first functional layer 221a may be disposed on the pixel electrode 210, and the second functional layer 221b may be disposed on the first functional layer 221a. The first functional layer 221a and the second functional layer 221b may serve as a hole injection layer HIL. The third functional layer 222 may be disposed on the second functional layer 221b. The third functional layer 222 may serve as a hole transport layer HTL.

The first functional layer 221a, the second functional layer 221b, and the third functional layer 222 may be defined as a hole transport region through which holes may be transported. In an embodiment, the hole transport region may further include at least one layer selected from an emission support layer and an electron blocking layer, as well as the hole injection layer HIL and the hole transport layer HTL. Thicknesses of the hole injection layer HIL, the hole transport layer HTL, the emission support layer, and the electron blocking layer may be different from each other, but a thickness t1 of the hole injection layer HIL may be relatively the greatest.

For example, the hole transport region may have a single-layer structure including a single layer including different materials or a multi-layer structure including the hole injection layer/the hole transport layer, the hole injection layer/the hole transport layer/the emission support layer, the hole injection layer/the emission support layer, the hole transport layer/the emission support layer, or the hole injection layer/the hole transport layer/the electron blocking layer, which may be sequentially stacked on the pixel electrode 210, but one or more embodiments are not limited thereto.

In an embodiment, the organic light-emitting diode OLED of FIG. 5 may include, as the hole transport region, the first functional layer 221a and the second functional layer 221b as the hole injection layer HIL and the third functional layer 222 as the hole transport layer HTL. The hole injection layer HIL may be adjacent to the pixel electrode 210, and the hole transport layer HTL may be disposed on the hole injection layer HIL.

The hole injection layer HIL may facilitate injection of holes and may include one or more selected from the group including HATCN, copper phthalocyanine (CuPc), poly(3,4)-ethylenedioxythiophene (PEDOT), polyaniline (PANI), and N, N-dinaphthyl-N, N′-diphenylbenzidine (NPD), but one or more embodiments are not limited thereto.

The hole transport layer HTL may include a triphenylamine derivative having high hole mobility and excellent stability, such as TCTA, N, N′-diphenyl-N,N′-bis(3-methylphenyl)-1,1′-bi-phenyl-4,4′-diamine (TPD), or N,N′-di(naphthalen-1-yl)-N,N′-diphenyl-benzidine (NPB), as a host of the hole transport layer HTL. Although FIG. 5 shows the hole transport layer HTL as a single layer, the hole transport layer HTL may have a multi-layer structure. The hole transport layer HTL may have a multi-layer structure of two or more layers each including a different material from among the above-described materials. For example, the hole transport layer HTL may have two layers including NPB and TCTA, respectively.

The organic emission layer 223 may be disposed on the third functional layer 222. The organic emission layer 223 may include an organic material emitting one of red light, blue light, and green light. For example, in case that the organic emission layer 223 emits red light, the organic emission layer 223 may be formed by using, for example, a red dopant in a certain host material. In other embodiments, in case that the organic emission layer 223 emits green light, the organic emission layer 223 may be formed by using, for example, a green dopant in a certain host material. In other embodiments, in case that the organic emission layer 223 emits blue light, the organic emission layer 223 may be formed by using, for example, a blue dopant in a certain host material.

The fourth functional layer 224 and the fifth functional layer 225 may be disposed on the organic emission layer 223. The fourth functional layer 224 may be disposed on the organic emission layer 223, and the fifth functional layer 225 may be disposed on the fourth functional layer 224. The fourth functional layer 224 may serve as an electron transport layer ETL, and the fifth functional layer 225 may serve as an electron injection layer EIL.

The fourth functional layer 224 and the fifth functional layer 225 may be defined as an electron transport region. The electron transport region may include at least one layer selected from a buffer layer, a hole blocking layer, an electron adjusting layer, the electron transport layer ETL, and the electron injection layer EIL, but one or more embodiments are not limited thereto.

For example, the electron transport region may have a structure of the electron transport layer/the electron injection layer, the hole blocking layer/the electron transport layer/the electron injection layer, the electron adjusting layer/the electron transport layer/the electron injection layer, the buffer layer/the electron transport layer/the electron injection layer, or the like, which may be sequentially stacked on the organic emission layer 223, but one or more embodiments are not limited thereto.

The electron transport region may include at least one compound selected from 2,9-Dimethyl-4,7-diphenyl-1,10-phenanthroline (BCP), 4,7-Diphenyl-1,10-phenanthroline (Bphen), Alq3, BAlq, 3-(Biphenyl-4-yl)-5-(4-tert-butylphenyl)-4-phenyl-4H-1,2,4-triazole (TAZ), NTAZ, diphenyl(4-(triphenylsilyl)phenyl)-phosphine oxide (TSPO1), and 3P-T2T.

Each of the layers constituting the intermediate layer 220 may include a photocurable composition so that each discharged ink may be cured by a curing reaction.

The opposite electrode 230 may be disposed on the fifth functional layer 225.

FIG. 6 is a schematic cross-sectional view of a portion of an organic light-emitting display apparatus according to an embodiment.

Referring to FIG. 6, an organic light-emitting display apparatus according to an embodiment may include a thin-film transistor TFT disposed above a substrate 100 and may include a buffer layer 201, a gate insulating layer 203, an interlayer insulating layer 205, a planarization layer 207, and a pixel-defining layer 209, which may be insulating layers. The thin-film transistor TFT may be one of the thin-film transistors in the pixel circuit PC described with reference to FIGS. 2 to 4.

The buffer layer 201 may be located on the substrate 100 to decrease or prevent penetration of a foreign material, moisture, or external air from below the substrate 100 and may provide a flat surface on the substrate 100. The buffer layer 201 may include an inorganic material, such as oxide or nitride, an organic material, or an organic-inorganic compound, and may have a single-layer or multi-layer structure including an inorganic material and an organic material. A barrier layer (not shown) that prevents penetration of external air may be further between the substrate 100 and the buffer layer 201. The buffer layer 201 may include silicon oxide (SiO₂) or silicon nitride (SiNx).

The thin-film transistor TFT may be disposed on the buffer layer 201. The thin-film transistor TFT may include a semiconductor layer ACT, a gate electrode GE, a source electrode SE, and a drain electrode DE. The thin-film transistor TFT may be connected to the organic light-emitting diode OLED to drive the organic light-emitting diode OLED.

The semiconductor layer ACT may be disposed on the buffer layer 201 and may include polysilicon. In other embodiments, the semiconductor layer ACT may include amorphous silicon. In other embodiments, the semiconductor layer ACT may include oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel region and source and drain regions doped with impurities.

The gate electrode GE, the source electrode SE, and the drain electrode DE may include various conductive materials. The gate electrode GE may include at least one of molybdenum, aluminum, copper, and titanium. For example, the gate electrode GE may include a single layer of molybdenum or may have a three-layer structure including a molybdenum layer, an aluminum layer, and a molybdenum layer. The source electrode SE and the drain electrode DE may include at least one material selected from the group including copper, titanium, and aluminum. For example, the source electrode SE and the drain electrode DE may have a three-layer structure including a titanium layer, an aluminum layer, and a titanium layer.

To insulate the semiconductor layer ACT and the gate electrode GE from each other, the gate insulating layer 203 including an inorganic material, such as silicon oxide, silicon nitride and/or silicon oxynitride, may be disposed between the semiconductor layer ACT and the gate electrode GE. The interlayer insulating layer 205 including an inorganic material, such as silicon oxide, silicon nitride and/or silicon oxynitride, may be disposed on the gate electrode GE, and the source electrode SE and the drain electrode DE may be disposed on the interlayer insulating layer 205. Such insulating layers including an inorganic material may be formed through chemical vapor deposition (CVD) or atomic layer deposition (ALD). The same applies to the following embodiments.

The planarization layer 207 may be disposed over the thin-film transistor TFT. To provide a flat upper surface, chemical mechanical polishing may be performed on an upper surface of the planarization layer 207 after the planarization layer 207 may be formed. The planarization layer 207 may include a general commercial polymer, such as photosensitive polyimide, polyimide, polycarbonate (PC), benzocyclobutene (BCB), hexamethyldisiloxane (HMDSO), poly(methyl methacrylate) (PMMA), and/or polystyrene (PS), a polymer derivative having a phenol-based group, an acryl-based polymer, an imide-based polymer, an aryl ether-based polymer, an amide-based polymer, a fluorine-based polymer, a p-xylene-based polymer, and/or a vinyl alcohol-based polymer. Although FIG. 6 shows the planarization layer 207 as a single layer, the planarization layer 207 may include multiple layers.

The organic light-emitting diode OLED may be disposed on the planarization layer 207. The organic light-emitting diode OLED may include the pixel electrode 210, the intermediate layer 220, and the opposite electrode 230.

The pixel electrode 210 may be disposed on the planarization layer 207. The pixel electrode 210 may be arranged for each pixel. Pixel electrodes 210 respectively corresponding to neighboring pixels may be apart from each other.

The pixel electrode 210 may be a reflective electrode. The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), and/or a compound thereof, and/or a transparent or semitransparent conductive layer on the reflective film. The transparent or semitransparent conductive layer may include at least one material selected from the group including indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 210 may have a stack structure of ITO/Ag/ITO.

The pixel-defining layer 209 may be disposed on the pixel electrode 210 as an insulating layer. The pixel-defining layer 209 may have an opening 209OP exposing the central portion of each pixel electrode 210. The pixel-defining layer 209 may cover the edge of the pixel electrode 210, and may prevent an arc, etc. from occurring at the edge of the pixel electrode 210 by increasing a distance between the edge of the pixel electrode 210 and the opposite electrode 230.

The pixel-defining layer 209 may include an organic insulating material. In other embodiments, the pixel-defining layer 209 may include an inorganic insulating material, such as silicon nitride, silicon oxynitride, and/or silicon oxide.

The intermediate layer 220 may be disposed on the pixel electrode 210. In an embodiment, the intermediate layer 220 may have a stacked structure described with reference to FIG. 5. FIG. 6 shows, as an example, a structure in which the intermediate layer 220 includes the first functional layer 221a, the second functional layer 221b, the third functional layer 222, the organic emission layer 223, and the fourth functional layer 224. As shown in FIG. 5, the intermediate layer 220 may further include the fifth functional layer 225.

Each of the layers constituting the intermediate layer 220 may be present in a patterned form on the pixel electrode 210. For example, each of the first functional layer 221a, the second functional layer 221b, the third functional layer 222, the organic emission layer 223, and the fourth functional layer 224 may be individually formed for the pixel electrode 210 corresponding to each pixel P. In this regard, being individually formed may mean that each of the layers constituting the intermediate layer 220 is independently formed for each pixel P. Each of the first functional layer 221a, the second functional layer 221b, the third functional layer 222, the organic emission layer 223, and the fourth functional layer 224 constituting the intermediate layer 220 may be formed by using an inkjet printing method. The first functional layer 221a, the second functional layer 221b, the third functional layer 222, the organic emission layer 223, and the fourth functional layer 224 may be the same as described above with reference to FIG. 5, and thus, a repeated description thereof is omitted.

The opposite electrode 230 may be a cathode, which may be an electron injection electrode. The opposite electrode 230 may include a conductive material having a low work function. For example, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), ytterbium (Yb), and/or an alloy thereof. As an example, the opposite electrode 230 may include AgMg or AgYb. In other embodiments, the opposite electrode 230 may further include a layer, such as ITO, IZO, ZnO, and/or In₂O₃, on a (semi)transparent layer including the above-described material. The layers from the pixel electrode 210 to the opposite electrode 230 may constitute the organic light-emitting diode OLED.

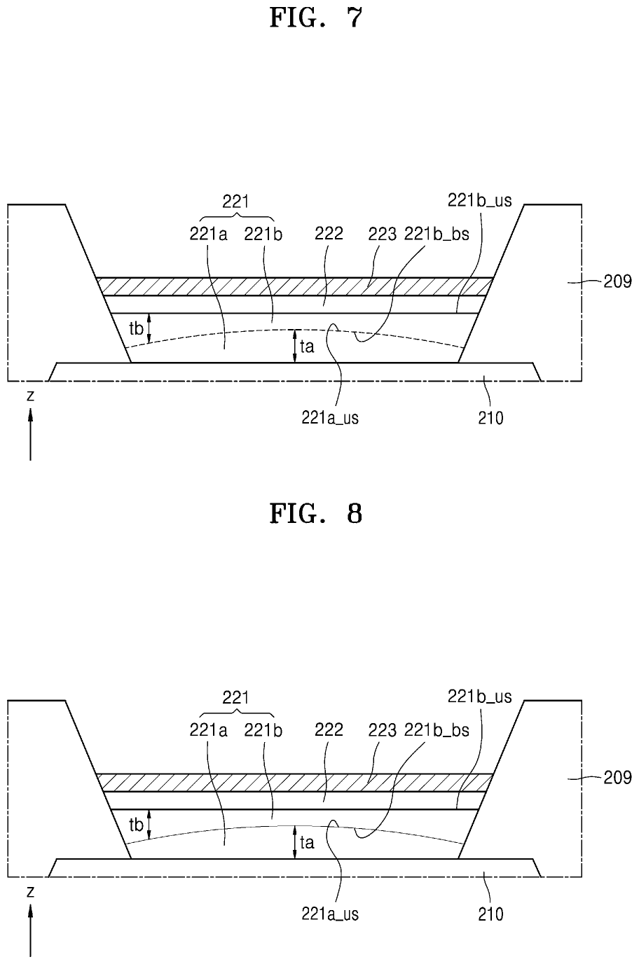

FIGS. 7 and 8 are enlarged schematic cross-sectional views of an intermediate layer of an organic light-emitting diode according to an embodiment.

Referring to FIGS. 7 and 8, the intermediate layer 220 according to an embodiment may include the first functional layer 221a and the second functional layer 221b on the pixel electrode 210.

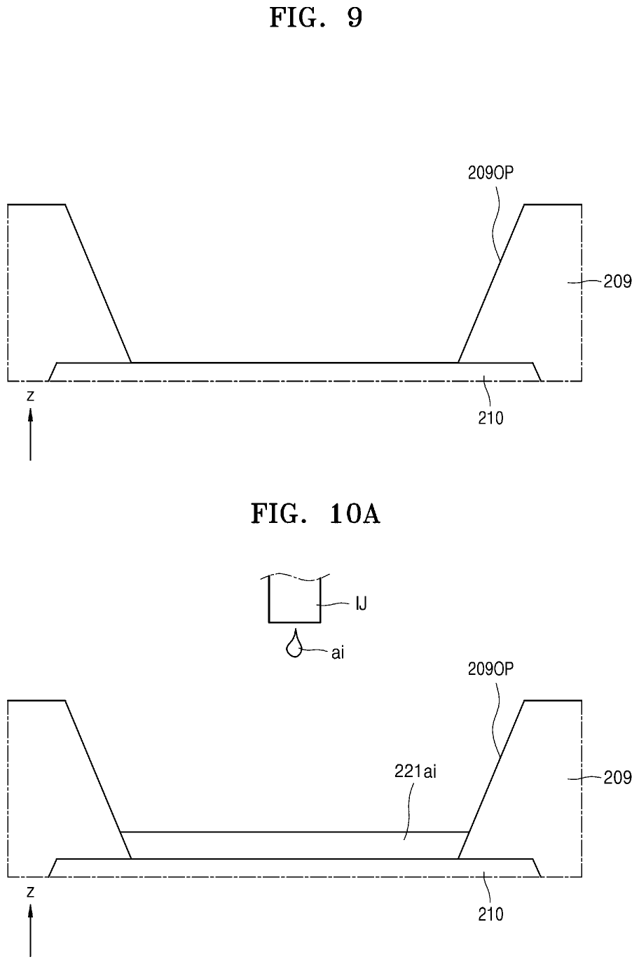

In an embodiment, as shown in FIG. 7, the first functional layer 221a and the second functional layer 221b may include the same material selected from materials having a hole injection function. As will be described in detail later in FIG. 9 and below, the first functional layer 221a and the second functional layer 221b may have different molecular weights from each other. As an example, a molecular weight of the first functional layer 221a at a lower position may be greater than a molecular weight of the second functional layer 221b at an upper position. This may be because the first functional layer 221a undergoes two curing processes, whereas the second functional layer 221b undergoes one curing process.

An interface between the first functional layer 221a and the second functional layer 221b may be confirmed through a residual solvent or a surface oxide film generated during a process of curing and drying the first functional layer 221a.

In an embodiment, as shown in FIG. 8, the first functional layer 221a and the second functional layer 221b may include different materials selected from materials having a hole injection function. As shown in FIG. 8, in case that the first functional layer 221a and the second functional layer 221b include different materials from each other having a hole injection function, a boundary between the first functional layer 221a and the second functional layer 221b may appear clear.

An upper surface 221a_us of the first functional layer 221a may be convex. Although only cross-sections are shown in FIGS. 7 and 8, the upper surface 221a_us of the first functional layer 221a may substantially have a convex lens shape or a partial sphere shape. A thickness ta of the first functional layer 221a may be greatest at the central portion of the pixel electrode 210 exposed through an opening of the pixel-defining layer 209 and may decrease toward the opening of the pixel-defining layer 209.

A bottom surface 221b_bs of the second functional layer 221b may contact the upper surface 221a_us of the first functional layer 221a. For example, the second functional layer 221b may be disposed on (e.g., directly on) the first functional layer 221a. The bottom surface 221b_bs of the second functional layer 221b may be concave. Although only cross-sections are shown in FIGS. 7 and 8, the bottom surface 221b_bs of the second functional layer 221b may substantially have a concave lens shape. A thickness tb of the second functional layer 221b may be least at the central portion of the pixel electrode 210 exposed through the opening of the pixel-defining layer 209 and may gradually increase toward the opening of the pixel-defining layer 209.

An upper surface 221b_us of the second functional layer 221b may be substantially flat. This may be because, as described above, the thickness ta of the first functional layer 221a may be greatest at the central portion of the pixel electrode 210 exposed through the opening of the pixel-defining layer 209 and decreases toward the opening of the pixel-defining layer 209, and the thickness tb of the second functional layer 221b may be least at the central portion of the pixel electrode 210 exposed through the opening of the pixel-defining layer 209 and gradually increases toward the opening of the pixel-defining layer 209. As the first functional layer 221a and the second functional layer 221b may be vertically stacked, the thickness of a hole injection layer 221 including the first functional layer 221a and the second functional layer 221b may be uniformly maintained overall, and the upper surface of the hole injection layer 221, for example, the upper surface 221bs_us of the second functional layer 221b, may be substantially flat.

As a comparative example, as described above, the thickness tb of the second functional layer 221b may be least at the center and may gradually increase toward an opening of the pixel-defining layer 209, and in case that the first functional layer 221ais not under the second functional layer 221b, for example, in case that a surface on which the second functional layer 221b is formed is flat, the upper surface of the second functional layer 221b may be concave. In general, the edge of the second functional layer 221b, for example, a portion adjacent to the opening of the pixel-defining layer 209, extends up an inner side surface of the opening of the pixel-defining layer 209, and thus, the second functional layer 221b may be thicker at the edge than at the center thereof. However, in the organic light-emitting diode OLED according to an embodiment, the first functional layer 221a in which the upper surface 221a_us may be convex may be disposed at a lower position and the second functional layer 221b may be disposed on the first functional layer 221a to allow the upper surface of the hole injection layer 221 (for example, the upper surface 221b_us of the second functional layer 221b) to have a flat shape, thereby readily controlling emission uniformity of the organic emission layer 223 formed thereon.

While an organic light-emitting display apparatus has been described thus far, one or more embodiments are not limited thereto. For example, it will be understood that a method of manufacturing an organic light-emitting display apparatus for forming such an organic light-emitting display apparatus also falls within the scope of the disclosure.

FIGS. 9 to 12 are schematic cross-sectional views of a method of manufacturing an organic light-emitting display apparatus, according to an embodiment.

Hereinafter, an operation of forming the pixel electrode 210 will be described with reference to FIG. 9, and processes of the previous operation for forming the pixel electrode 210 may be the same as described above with reference to FIG. 6 and thus a description thereof is omitted.

Referring to FIG. 9, after the pixel electrode 210 may be patterned, the pixel-defining layer 209 may be formed on the pixel electrode 210. The opening 209OP exposing the central portion of the pixel electrode 210 and covering the edge of the pixel electrode 210 may be formed in the pixel-defining layer 209.

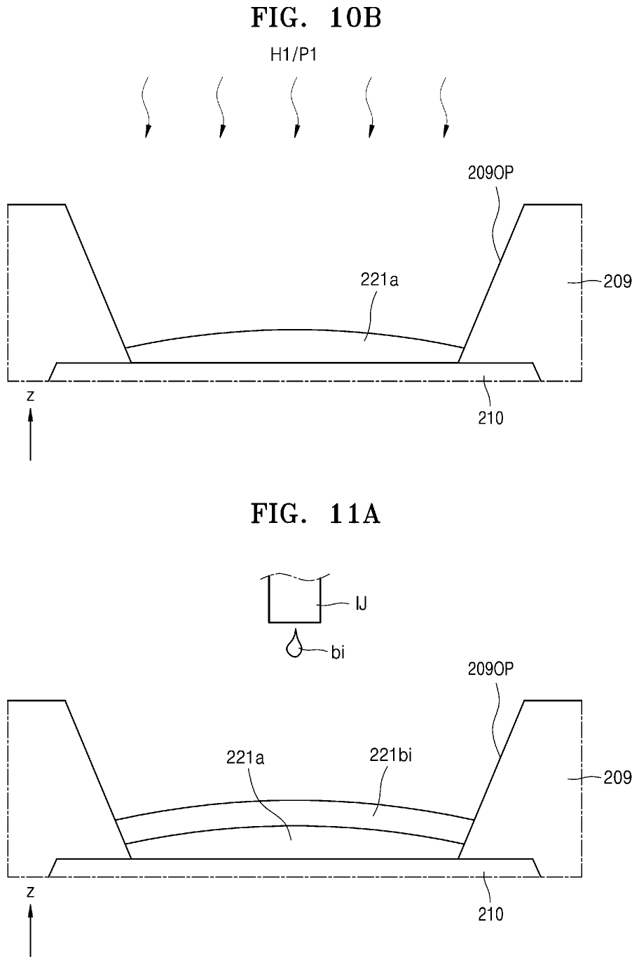

Thereafter, referring to FIGS. 10A and 10B, the first functional layer 221a may be formed on the pixel electrode 210 exposed through the opening 209OP. First, as shown in FIG. 10A, a first functional layer ink layer 221ai may be formed by discharging, through an inkjet nozzle IJ, first functional layer ink ai onto the pixel electrode 210 exposed through the opening 209OP. As shown in FIG. 10B, the first functional layer 221a may be formed by curing the first functional layer ink layer 221ai under a first temperature H1 and a first pressure P1 in a chamber. During a process of curing the first functional layer 221a, the upper surface 221a_us of the first functional layer 221a may have a convex shape.

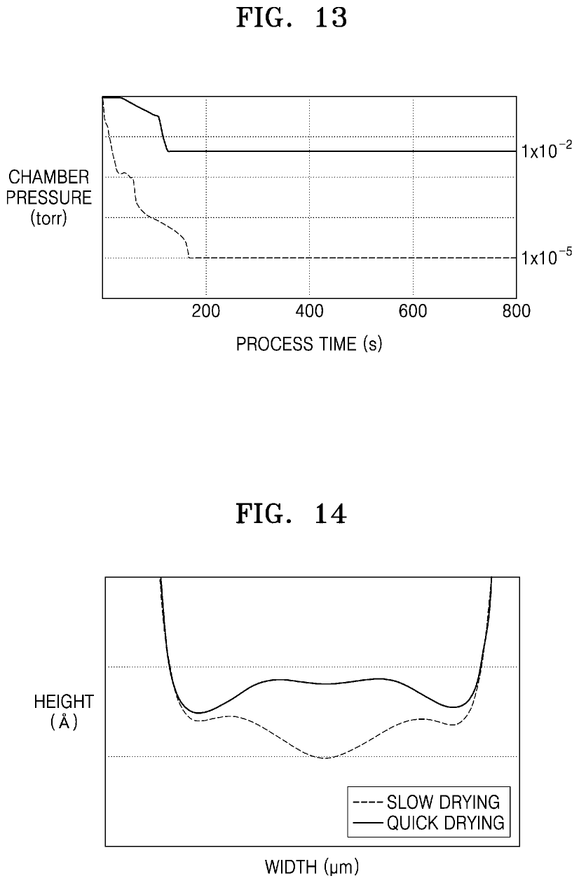

The process of curing the first functional layer 221a will be described in more detail. Referring to FIGS. 10B and 12 together, the process of curing the first functional layer 221a may employ a so-called ‘quick drying’ method. FIG. 13 is a schematic graph showing pressure in the chamber applied to a ‘quick drying’ method applied to the first functional layer 221a and a ‘slow drying’ method applied to the second functional layer 221b, which will be described below.

Specifically, conditions in the chamber may be controlled to be the first temperature H1 and the first pressure P1, which may mean being performed at a high temperature and low pressure. As an example, the first temperature H1 may be controlled at about 50° C. or greater, and the first pressure P1 may be controlled at about 1×10⁻⁵ Torr or less. In this regard, a process of reducing pressure to the first pressure P1 may be an operation of rapidly reducing pressure in the chamber by using a turbo pump. The time for which the first pressure P1 may be reduced to 1×10⁻⁵ Torr or less may be approximately 200 seconds or less, for example, 100 seconds or less.

The first functional layer 221a formed under such conditions has the same shape as the first functional layer 221a described with reference to FIGS. 5 to 8. For example, the shape of the first functional layer 221a may be formed through the above-described curing process.

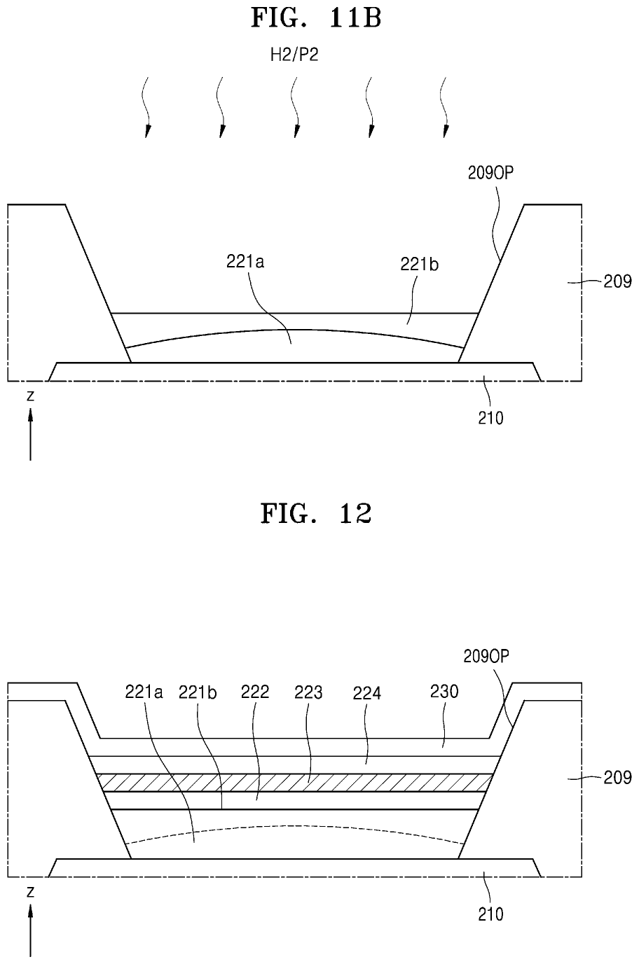

Thereafter, referring to FIGS. 11A and 11B, the second functional layer 221b may be formed on the first functional layer 221a. First, as shown in FIG. 11A, a second functional layer ink layer 221bi may be formed by discharging second functional layer ink bi onto the first functional layer 221a through the inkjet nozzle IJ. In case that the second functional layer ink layer 221bi is formed by discharging the second functional layer ink bi onto the first functional layer 221a, as shown in FIG. 11A, the upper surface of the second functional layer ink layer 221bi may have a convex shape along the shape of the upper surface of the first functional layer 221a at a lower position. However, the upper surface of the second functional layer 221b may be substantially flattened through a curing (drying) process described below.

As shown in FIG. 11B, the second functional layer 221b may be formed by curing the second functional layer ink layer 221bi under a second temperature H2 and a second pressure P2 in the chamber. During a process of curing the second functional layer 221b, the upper surface 221b_us of the second functional layer 221b may end up having a flat shape.

The process of curing the second functional layer 221b will be described in more detail. Referring to FIGS. 11B and 12 together, the process of curing the second functional layer 221b may employ a so-called ‘slow drying’ method. Specifically, conditions in the chamber may be controlled to be the second temperature H2 and the second pressure P2, which may mean being performed at a relatively low temperature and high pressure compared to the first temperature H1 and the first pressure P1 described above. As an example, the second temperature H2 may be maintained at less than about 50° C., and the second pressure P2 may be maintained at about 1×10⁻² Torr or greater. In this regard, a process of reducing pressure to the second pressure P2 may be performed slower than that described above. During this process, a turbo pump may not be used.

The second functional layer 221b formed under such conditions has the same shape as the second functional layer 221b described with reference to FIGS. 5 to 8. For example, the shape of the second functional layer 221b may be formed through the above-described curing process.

The upper surface of the hole injection layer 221 including the first functional layer 221a and the second functional layer 221b may be substantially planarized. This may be because, as described above, different conditions may be applied respectively during the processes of curing (drying) the first functional layer 221a and the second functional layer 221b. By controlling the curing (drying) conditions differently in this way, different profiles of the first functional layer 221a and the second functional layer 221b may be formed, and thus, the upper surface of the hole injection layer 221 in which the first functional layer 221a and the second functional layer 221b are vertically stacked may be planarized.

Thereafter, referring to FIG. 12, after the third functional layer 222, the organic emission layer 223, and the fourth functional layer 224 are sequentially formed on the hole injection layer 221, the opposite electrode 230 may be formed. By planarizing the upper surface of the hole injection layer 221, the uniformity of the organic emission layer 223 disposed above the hole injection layer 221 may be readily increased.

FIG. 14 is a schematic graph showing profiles of functional layers formed in case that ‘quick drying’ and ‘slow drying’ according to the disclosure are applied respectively thereto.

Referring to FIG. 14, in case that a layer to which ‘quick drying’ is applied is referred to as a first functional layer, it may be seen that a profile of the first functional layer has a convex upper surface. On the other hand, in case that a layer to which ‘slow drying’ is applied is referred to as a second functional layer, it may be seen that a profile of the second functional layer has a concave upper surface. Both of the first functional layer and the second functional layer are the result of forming a surface to be formed on a planarized surface. For example, while the thickness of the first functional layer may be greatest at the center thereof and decreases toward the edge thereof, the thickness of the second functional layer may be least at the center thereof and increases toward the edge thereof, and accordingly, in case that the first functional layer and the second functional layer are vertically stacked according to an embodiment, the total thickness thereof may be uniformly formed, and the upper surface of the second functional layer at an upper position may be planarized.

According to one or more of the above embodiments, an organic light-emitting display apparatus in which the flatness of a thin film may be improved by eliminating the non-uniformity of an organic thin film layer and a method of manufacturing the organic light-emitting display apparatus may be implemented. However, one or more embodiments are not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. An organic light-emitting display apparatus comprising:
a pixel electrode above a substrate;
an insulating layer covering an edge of the pixel electrode and including an opening exposing a central portion of the pixel electrode;
a first functional layer disposed on the pixel electrode exposed by the opening and including a convex upper surface;
a second functional layer disposed on the first functional layer and including a planarized upper surface;
an organic emission layer disposed on the second functional layer; and
an opposite electrode disposed on the organic emission layer.

2. The organic light-emitting display apparatus of claim 1, wherein the first functional layer includes a hole injection function.

3. The organic light-emitting display apparatus of claim 1, wherein the second functional layer includes a hole injection function.

4. The organic light-emitting display apparatus of claim 1, wherein the first functional layer and the second functional layer comprise a curable material.

5. The organic light-emitting display apparatus of claim 1, wherein a bottom surface of the second functional layer is concave.

6. The organic light-emitting display apparatus of claim 5, wherein a thickness of the second functional layer is least at a center thereof and gradually increases toward the insulating layer.

7. The organic light-emitting display apparatus of claim 1, wherein molecular weights of the first functional layer and the second functional layer are different from each other.

8. The organic light-emitting display apparatus of claim 6, wherein a molecular weight of the first functional layer is greater than a molecular weight of the second functional layer.

9. The organic light-emitting display apparatus of claim 1, wherein the first functional layer and the second functional layer comprise a same material as each other or different materials from each other.

10. A method of manufacturing an organic light-emitting display apparatus, the method comprising:
forming a pixel electrode above a substrate;
forming an insulating layer covering an edge of the pixel electrode and including an opening exposing a central portion of the pixel electrode;
forming a first functional layer on the pixel electrode exposed by the opening, the first functional layer including a convex upper surface;
forming a second functional layer on the first functional layer, the second functional layer including a planarized upper surface;
forming an organic emission layer on the second functional layer; and
forming an opposite electrode on the organic emission layer.

11. The method of claim 10, wherein the forming of the first functional layer comprises:
setting a temperature in a chamber to a first temperature;
reducing pressure in the chamber to a first pressure; and
drying the first functional layer under conditions of the first temperature and the first pressure.

12. The method of claim 11, wherein the forming of the second functional layer comprises:
setting the temperature in the chamber to a second temperature that is lower than the first temperature;
controlling the pressure in the chamber to a second pressure that is higher than the first pressure; and
drying the second functional layer under conditions of the second temperature and the second pressure.

13. The method of claim 12, wherein
the first temperature is about 50° C. or greater, and
the second temperature is less than about 50° C.

14. The method of claim 12, wherein the second pressure is maintained at about 0.01 Torr or greater.

15. The method of claim 11, wherein the first pressure is about 1×10⁻⁵ Torr or less.

16. The method of claim 11, wherein the second functional layer is formed after the first functional layer is cured.

17. The method of claim 10, wherein the first functional layer and the second functional layer include a hole injection function.

18. The method of claim 10, wherein the first functional layer and the second functional layer comprise a curable material.

19. The method of claim 10, wherein a bottom surface of the second functional layer is concave.

20. The method of claim 19, wherein a thickness of the second functional layer is least at a center thereof and gradually increases toward the insulating layer.
